(19) United States
(12) Patent Application Publication
(10) Pub. No.: US 2012/0061834 A1
(43) Pub. Date: Mar. 15, 2012

(54) SEMICONDUCTOR CHIP, STACKED CHIP SEMICONDUCTOR PACKAGE INCLUDING THE SAME, AND FABRICATING METHOD THEREOF

(75) Inventor: Tae Min KANG, Seoul (KR)

(73) Assignee: HYNIX SEMICONDUCTOR INC., Icheon-si (KR)

(21) Appl. No.: 13/226,564

(22) Filed: Sep. 7, 2011

(30) Foreign Application Priority Data
Sep. 9, 2010 (KR) 10-2010-0088560

(51) Int. Cl. H01L 23/48; H01L 21/60

(52) U.S. Cl. 257/738; 438/121; 257/741; 257/E21.506; 257/E23.011; 257/E23.021

(57) ABSTRACT

A semiconductor chip includes a silicon wafer formed with a via hole, a metal wire disposed in the via hole, and a filler that exposes a part of an upper portion of the metal wire while filing the via hole.

### CROSS-REFERENCES TO RELATED APPLICATIONS

The present application claims priority under 35 U.S.C. 119(a) to Korean Application No. 10-2010-0088560, filed on Sep. 9, 2010, in the Korean intellectual property Office, which is incorporated herein by reference in its entirety.

### BACKGROUND

Exemplary embodiments of the present invention relate generally to a semiconductor package, and more particularly, to a semiconductor chip, a stacked chip semiconductor package including the same, and a fabricating method thereof.

Small sized, high performing modern electronic products require ultra-miniaturized, high memory capacity semiconductor memories. To improve the storage capacity, a semiconductor memory can be made with a semiconductor chip that is more highly integrated and in a semiconductor package having a plurality of chips. Packaging is generally considered to be more effective and less costly to increase storage capacity as compared to improving the degree of high integration.

A multi-chip package includes a plurality of semiconductor chips that are mounted in a semiconductor package. As more chips of larger size are stacked, insufficient electrical interconnection space is found in a package. That is, to attach a plurality of chips to the chip attachment areas of a board, required are a space for wire bonding and a circuit pattern area of the board connected to the wires since bonding pads of the chips are electrically connected to conductive circuit patterns using wires. This increases the size of a semiconductor package. A through-silicon via (TSV) is an example of the multi-chip package technology. A package employing a through-silicon via are formed with chips with through-silicon vias that were formed in the chips in a wafer level, and many physical and electrical connections are between the vertically stacked chips through the through-silicon vias.

In general, one through-silicon via is connected to one pad. When a through-silicon via is not appropriately formed (due to, for example, a metal film not completely filling in the via hole and causing the pad to open), it would not be possible to repair such a defective through-silicon via. For example, when a through-silicon via is filled by a plating process among many other processes having similar problems, the metal film often cannot completely fill the via hole as the height of a via hole increases and the diameter of the via hole is reduced. When a package is tested to include a chip with a defective through-silicon via as described above, all the other chips of the package also end up being discarded, resulting in reduction of productivity.

### SUMMARY

An embodiment of the present invention relates to a semiconductor chip, a stacked chip semiconductor package including the same, and a fabricating method thereof, which substantially prevent a pad open failure due to incomplete filling of a via hole by a metal film in the process of fabricating a through-silicon via of a semiconductor chip, thereby substantially preventing a void trap.

In an embodiment, a semiconductor chip includes: a silicon wafer formed with a via hole; a metal wire disposed in the via hole; and a filler that exposes a part of an upper portion of the metal wire while filing the via hole.

In an embodiment, the semiconductor chip may further include: a circuit board disposed at one surface of the silicon wafer where a bottom portion of the metal wire is positioned, and including a metal pad to which the metal wire is attached; and a stack via formed by removing a part of the silicon wafer and exposing a part of a surface of a metal pad.

The circuit board may have bending and adhesive properties.

The metal wire may include copper and have a reverse T shape, and the filler may be an underfill material including epoxy or a material including polymer.

In an embodiment, a semiconductor package may include: a plurality of stacked semiconductor chips including a silicon wafer formed with a via hole, a metal wire disposed in the via hole, and a filler that exposes a part of an upper portion of the metal wire while filing the via hole; and a solder ball including the exposed part of the upper portion of the metal wire and connecting the semiconductor chips to each other.

In an embodiment, a method of fabricating a semiconductor chip includes: preparing a circuit board including a metal pad; attaching a metal wire to the metal pad of the circuit board; forming a via hole in a silicon wafer; attaching the circuit board to the silicon wafer such that the metal wire is positioned in the via hole; and filling the via hole with a filler and exposing an upper portion of the metal wire.

In an embodiment, a method of fabricating a semiconductor package includes: preparing a first semiconductor chip including a first silicon wafer formed with a first via hole, a first metal wire disposed in the first via hole, and a first filler that exposes a part of an upper portion of the first metal wire while filing the first via hole; preparing a second semiconductor chip including a second silicon wafer formed with a second via hole, a second metal wire disposed in the second via hole, and a second filler that exposes a part of an upper portion of the second metal wire while filing the second via hole; and connecting the first semiconductor chip to the second semiconductor chip using a solder ball such that an exposed upper portion of the first metal wire of the first semiconductor chip is connected to a bottom surface of the second metal wire of the second semiconductor chip.

### BRIEF DESCRIPTION OF THE DRAWINGS

The above and other aspects, features and other advantages will be more clearly understood from the following detailed description taken in conjunction with the accompanying drawings, in which:

FIGS. 1a to 1g are diagrams relating to a method of fabricating a semiconductor chip according to an embodiment of the present invention;

FIG. 2 is a sectional view illustrating a semiconductor package including the semiconductor chips formed in FIGS. 1a to 1g according to an embodiment;

FIG. 3 is a diagram explaining a method for fabricating a semiconductor chip according to an embodiment of the present invention; and

FIG. 4 is a cross-sectional view illustrating a semiconductor package including semiconductor chips formed with stack vias.

### DESCRIPTION OF SPECIFIC EMBODIMENTS

Hereinafter, embodiments of the present invention will be described with reference to accompanying drawings. However, the embodiments are for illustrative purposes only and are not intended to limit the scope of the invention.

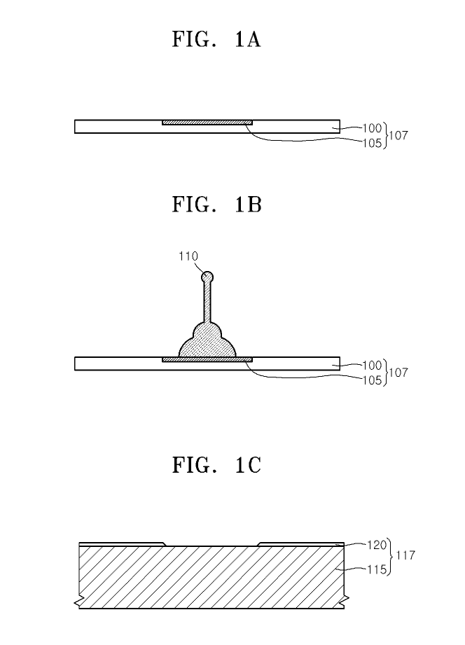

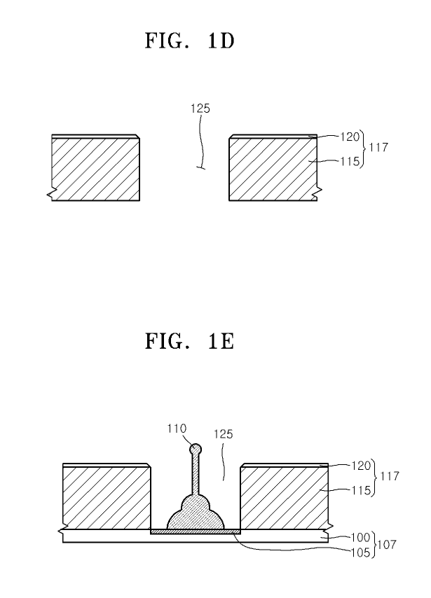

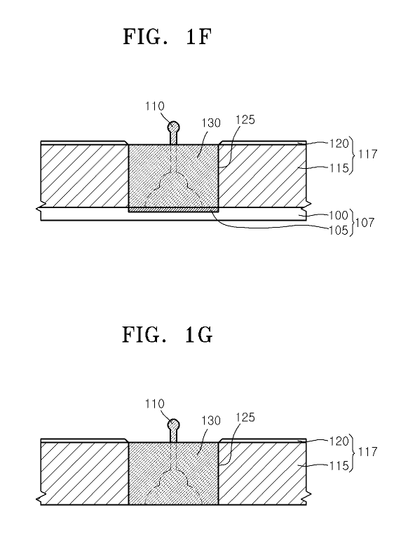

FIGS. 1a to 1g relate to a stacked chip semiconductor package according to an embodiment of the present invention.

Referring to FIG. 1a, a flexible circuit board (FCB) 107 comprises a metal pad 105 including a conductive metal such as copper (Cu) is formed on a portion of a polymer layer 100, which may exhibit bending properties. As shown in FIG. 1A, the metal pad 105 may be formed in the polymer layer 100 to provide a flat even surface, or the metal pad 105 may be formed in the polymer layer 100 to have a different surface level either above or below the surface of polymer layer 100. The flexible circuit board 107 may exhibit adhesive properties to accommodate a possible attachment to a silicon wafer or others in a later step. Alternatively, an adhesive material may be applied separately for attachment to a silicon wafer or others.

Referring to FIG. 1b, a metal wire 110 is attached to the metal pad 105 including, for example, the copper (Cu) of the circuit board 107, which may be flexible. The metal wire 110 may have a wide lower surface making contact with the metal pad 105 and a narrow upper surface, that is, the overall shape of the metal wire 110 formed on the metal pad 105 may be viewed as resembling an upside-down “T.” The metal wire 110 may include a conductive metal, for example, copper (Cu), so as to be easily attached to the metal pad 105. The overall height of the metal wire 110 may be greater than the thickness of a semiconductor chip, in order that a plurality of semiconductor chips can be connected to each other, more of which are explained below.

Referring to FIG. 1c, a semiconductor chip 117 may be formed with a through-silicon via. The semiconductor chip 117 includes a protective pattern 120 to expose an area of a silicon wafer 115 in which to form a via hole. The protective pattern 120 may be formed by coating polyimide isoindro quindzoline (PIQ) on a first surface of the silicon wafer 115.

Referring to FIG. 1d, a via hole 125 is formed by etching the portion of the semiconductor chip 117 exposed through the protective pattern 120 using a via mask (not shown) and the protective pattern 120. The exposed portion of the semiconductor chip 117 may be selectively etched in consideration of a target in a subsequent back grinding process.

Referring to FIG. 1e, the circuit board 107 of FIG. 1b having the metal pad 105 and the metal wire 110 is attached to the semiconductor chip 117. Since the circuit board 107 may be flexible and include the polymer layer 100 with adhesive properties according to an embodiment of the present invention, the circuit board 107 having the metal wire 110 as shown in FIG. 1B can be attached to the semiconductor chip 117 with ease. The circuit board 107 may be attached to the semiconductor chip 117 such that the metal wire 110 is positioned in the via hole 125 of the semiconductor chip 117.

Referring to FIG. 1f, a filler 130 is filled in the via hole 125 in which the metal wire 110 is inserted. The filler 130 by filling the via hole 125 clamps the metal wire 110 in the via hole 125 and substantially prevents a void from being formed in the via hole 125. The filler 130 may thus use a material with fluidity, for example, an underfill material including epoxy or polymer. Since the height of the metal wire 110 is greater than the thickness of the semiconductor chip 117, the end of the metal wire 100 is exposed out of the surface of the semiconductor chip 117.

Because the via hole 125 is filled with the filler 130 including a material with fluidity, it is possible to substantially prevent the occurrence of void, which may occur when a via hole is filled in with copper (Cu) using a conventional plating process, in accordance with an embodiment of the present invention.

Referring to FIG. 1g, the circuit board 107 is removed from the semiconductor chip 117. The circuit board 107 that may be flexible and having the adhesive properties can be selectively and easily separated from the semiconductor chip 117 while leaving the metal wire 110 to remain in the via hole 125. Then, a second surface, which corresponds to the first surface including the protective pattern 120 of the semiconductor chip 117, is exposed. When a plurality of semiconductor chips 117 are stacked, in the state in which the exposed second surface of the semiconductor chip 117 is employed as an upper surface and an exposed upper portion of the metal wire 110 is employed as a bottom surface, the semiconductor chips are stacked.

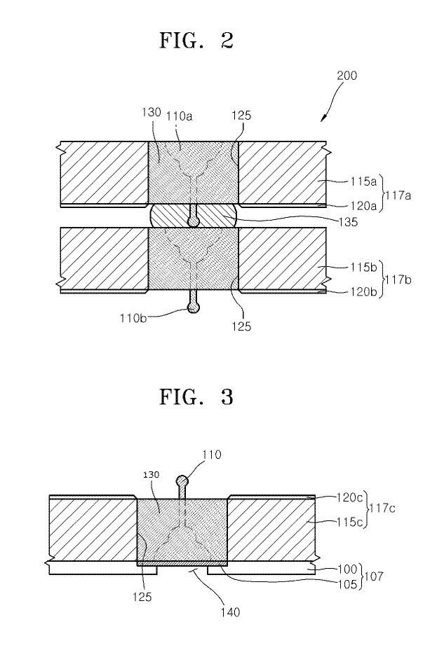

FIG. 2 is a cross-sectional view of a semiconductor package including the semiconductor chip formed in FIGS. 1a to 1g according to an embodiment of the present invention.

Referring to FIG. 2, a semiconductor package 200 according to an embodiment of the present invention has a structure in which a plurality of semiconductor chips such as a first semiconductor chip 117a and a second semiconductor chip 117b are stacked. The first and second semiconductor chips 117a, 117b are connected to each other through a solder ball 135 to form a package. The first and second semiconductor chips 117a, 117b are connected to each other through metal wires 110a, 110b, which are disposed in the via holes 125, using the solder ball 135, thereby forming a through electrode.

The semiconductor package 200 can be formed in such a manner that both the first semiconductor chip 117a including the metal wire 110a disposed in the via hole 125 and having an exposed upper portion and the second semiconductor chip 117b including the metal wire 110b disposed in the via hole 125 and having an exposed upper portion are prepared, and the first semiconductor chip 117a is connected to the second semiconductor chip 117b using the solder ball 135 such that the exposed upper portion of the metal wire 110a of the first semiconductor chip 117a is connected to the bottom surface of the metal wire 110b of the second semiconductor chip 117b.

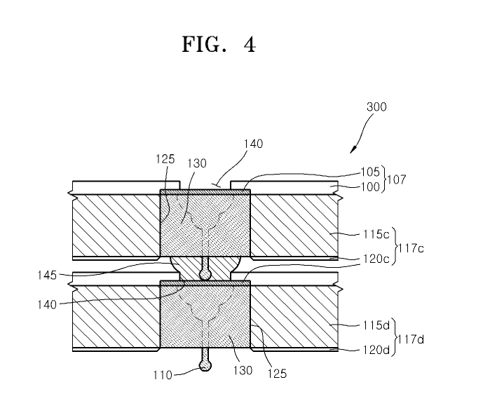

To prevent the metal wire 110 attached to the flexible circuit board 107 from being damaged when removing the flexible circuit board 107 from the semiconductor chip 117, the semiconductor chips may be stacked without removing the flexible circuit board 107. Hereinafter, this will be described with reference to FIGS. 3 and 4.

FIG. 3 relates to a semiconductor chip according to an embodiment of the present invention that may be packaged without removing a flexible circuit board.

Referring to FIG. 3, a filler 130 is filled in a vial hole 125 in which a metal wire 110 is disposed, and a polymer layer 100 of a flexible circuit board 107 is selectively etched to form a stack via 140 that exposes a part of the surface of a metal pad 105. The stack via 140 serves as a connection path through which a plurality of semiconductor chips is connected to each other when they are stacked later. The stack via 140 can be formed by selectively etching the polymer layer 100 using a laser. The second surface of a semiconductor chip 117c is covered by the flexible circuit board 107 and only a part of the surface of the metal pad 105 is exposed.

FIG. 4 is a cross-sectional view illustrating a semiconductor package including a semiconductor chips formed with stack vias.

Referring to FIG. 4, a semiconductor package 300 according to an embodiment of the present invention includes a plurality of semiconductor chips such as the vertically stacked first and second semiconductor chips 117c, 117d. The semiconductor chips 117c, 117d are connected to each other through a solder ball 145 to form a package. The first and second semiconductor chips 117c, 117d are connected to each other through metal wires 110, which are disposed in the via hole 125, using the solder ball 145, thereby forming a through-silicon via.

The semiconductor package 300 can be formed in such a manner that both the first semiconductor chip 117c including the metal wire 110 disposed in the via hole 125 and having an exposed upper portion and the second semiconductor chip 117d including the metal wire 110 disposed in the via hole 125 and having an exposed upper portion are prepared, and the first semiconductor chip 117c is connected to the second semiconductor chip 117d using the solder ball 145 such that the exposed upper portion of the metal wire 110 of the first semiconductor chip 117c is connected to the bottom surface of the metal wire 110 of the second semiconductor chip 117d. The solder ball 145 connects the first semiconductor chip 117c to the second semiconductor chip 117d while filling an empty space of the stack via 140.

According to the semiconductor chip and the semiconductor package of an embodiment, the via hole of the through-silicon via (TSV) is filled using a wire bonding technology, so that it is possible to substantially prevent a void defect which occurs when filling the via hole using a plating process. Furthermore, the wire bonding technology is used, so that it is possible to fill the via hole of the through-silicon via (TSV) at low cost.

According to an embodiment of the present invention, a wire bonding technology is applied to a method for filling a via hole of a through-silicon via (TSV), thereby substantially preventing a void trap which occurs when filling the via hole using a plating process. Furthermore, the wire bonding technology is used, so that it is possible to fill the via hole of the through-silicon via (TSV) at low cost.

The embodiments of the present invention have been disclosed above for illustrative purposes. Those skilled in the art will appreciate that various modifications, additions and substitutions are possible, without departing from the scope and spirit of the invention as disclosed in the accompanying claims.

What is claimed is:

1. A semiconductor chip having a via hole comprising:
a metal wire, at least a portion of which is in the via hole; and
a filler filling the via hole having the metal wire therein, wherein a first end portion of the metal wire is exposed out of the filler.

2. The semiconductor chip of claim 1, further comprising:
a circuit board having a portion formed with a metal pad, wherein the circuit board is disposed on one surface of the semiconductor chip so as to electrically connect the metal pad to a portion of the metal wire excluding the first end portion.

3. The semiconductor chip of claim 2, wherein the circuit board comprises a polymer layer with bending and adhesive properties, and wherein a stack via is formed in the circuit board to expose a portion of the metal pad that is not in contact with the metal wire.

4. The semiconductor chip of claim 1, wherein the metal wire comprises copper having a cross-sectional shape resembling a T.

5. The semiconductor chip of claim 1, wherein the filler is an underfill material comprising epoxy or a material including polymer.

6. A semiconductor package comprising:
first and second semiconductor chips, each chip having a via hole between the first and second surfaces of the chip comprising:
a metal wire, at least a portion of which is in the via hole; and
a filler filling the via hole having the metal wire therein, wherein a first end portion of the metal wire is exposed from the first surface and a second end portion is exposed from the second surface,
wherein the first end portion of the metal wire of the first chip is electrically connected to the second end portion of the metal wire of the second chip.

7. The semiconductor package of claim 6, wherein the first end portion of each chip protrudes out of the first surface of each chip and wherein the protruding first end portion of the metal wire of the first chip is electrically connected to the second end portion of the metal wire of the second chip by a solder ball.

8. The semiconductor package of claim 7, wherein each semiconductor chip further comprises:
a circuit board having a portion formed with a metal pad, wherein one surface of the circuit board is disposed at the second surface of the chip so as to electrically connect the metal pad to the second end portion of the metal wire; and
a stack via formed on the other surface of the circuit board so as to expose a part of the metal pad.

9. The semiconductor package of claim 7, wherein the metal wire comprises copper having a cross-sectional shape resembling a T.

10. The semiconductor package of claim 7, wherein the filler is an underfill material comprising epoxy or a material including polymer.

11. A method for fabricating a semiconductor chip having a via hole, comprising:
preparing a circuit board comprising a metal pad formed therein;
attaching a second end portion of a metal wire to the metal pad of the circuit board;
positioning the metal wire in the via hole; and
filling the via hole with a filler so as to expose a first end portion of the metal wire out of the filler.

12. The method of fabricating a semiconductor chip having a via hole, wherein the first end portion protrudes out of a surface of the semiconductor chip.

13. The method of claim 12, wherein the circuit board comprises a polymer layer with bending and adhesive properties.

14. The method of claim 12, wherein the metal wire comprises copper having a cross-sectional shape resembling a T shape.

15. The method of claim 12, wherein the filler is an underfill material comprising epoxy or a material including polymer.

16. The method of claim 12, further comprising:
after filling the via hole with the filler, removing the circuit board from the chip such that the metal wire is held in the via hole by the filler.

17. The method of claim 12, further comprising:
after filling the via hole with the filler, etching a portion of the circuit board to form a stack via that exposes a portion of the metal pad therethrough.

18. The method of claim 17, wherein the stack via is formed through an etch method using a laser.

19. A method of fabricating a semiconductor package, comprising:
fabricating first and second semiconductor chips, wherein each chip having a via hole is fabricated by a method comprising:
preparing a circuit board comprising a metal pad formed therein;
attaching a second end portion of a metal wire to the metal pad of the circuit board;
positioning the metal wire in the via hole; and
filling the via hole with a filler so as to expose a first end portion of the metal wire out of the filler such that the first end portion protrudes out of a surface of the semiconductor chip; and

20. The method of claim 19, further comprising:
connecting the first end portion of the metal wire of the first semiconductor chip to the second end portion of the metal wire of the second semiconductor chip by a solder ball.

21. The method of claim 19, wherein each semiconductor chip further comprises:
a circuit board having a portion formed with a metal pad, one surface of the circuit board is disposed at the second surface of the chip so as to electrically connect the metal pad to the second end portion of the metal wire; and
a stack via formed on the other surface of the circuit board so as to expose a portion of the metal pad,
wherein the first end portion of the metal wire of the first semiconductor chip is connected to the portion of the metal pad of the second semiconductor chip exposed through the stack via.
